(19) United States
(12) Patent Application Publication
(10) Pub. No.: US 2020/0002825 A1
(43) Pub. Date: Jan. 2, 2020

(54) SILICON PHOTOANODE COMPRISING A THIN AND UNIFORM PROTECTIVE LAYER MADE OF TRANSITION METAL DICHALCOGENIDE AND METHOD OF MANUFACTURING SAME

(71) Applicant: THE ROYAL INSTITUTION FOR THE ADVANCEMENT OF LEARNING/MCGILL UNIVERSITY, Montréal (CA)

(72) Inventors: Srinivas VANKA, Ann Arbor, MI (US); Zetian MI, Ann Arbor, MI (US)

(21) Appl. No.: 16/453,010

(22) Filed: Jun. 26, 2019

Related U.S. Application Data
(60) Provisional application No. 62/690,516, filed on Jun. 27, 2018.

(51) Int. Cl. C25B 11/04; H01L 21/20

(52) U.S. Cl. CPC C25B 11/0421; H01L 21/20; C25B 11/0447; C25B 11/0405

(57) ABSTRACT

There is described a silicon photoanode generally having a silicon-based substrate; and a protective layer covering the silicon-base substrate, the protective layer having a transition metal dichalcogenide (TMDC) material, being uniform and having a thickness below about 8 nm.

### FIELD

The improvements generally relate to the field of photoelectrochemical cells and more specifically relate to silicon photoanodes of such photoelectrochemical cells.

### BACKGROUND

Photoelectrochemical cells (sometimes referred to as “PECs”) are solar cells that produce electrical energy or hydrogen in a process similar to the electrolysis of water. Such cells generally involve electrolysation of water to hydrogen and oxygen gas by irradiating a silicon photoanode immerged in said water with electromagnetic radiation such as sunlight. In this way, incoming sunlight can excite free electrons near the surface of the silicon photoanode, which then flow through wires to a metal electrode, where four of them react with four water molecules to form two molecules of hydrogen and four OH groups. The OH groups flow through the liquid electrolyte to the surface of the silicon photoanode. There, the four OH groups react with the four holes associated with the four photoelectrons, the result being two water molecules and an oxygen molecule.

Although existing photoanodes are satisfactory to a certain degree, there remains room for improvement, especially as they can corrode under contact with the water, which can consume material of the silicon photoanode and disrupt the properties of the surfaces and interfaces within the photoelectrochemical cell.

### SUMMARY

In an aspect, there is described a silicon photoanode having a silicon substrate and a protective layer covering a surface of the silicon substrate. The inventors found that by applying a protective layer of transition metal dichalcogenide (TMDC) on the silicon substrate, the silicon substrate could be protected by corrosion-resistant properties of TMDC materials. However, to achieve satisfactory results, the thickness of the protective layer should be thin enough to allow sunlight to propagate through it to reach the silicon substrate while being sufficiently uniform so as to prevent defects of negatively affecting the propagation of the light through the protective layer.

In accordance with one aspect, there is provided a silicon photoanode comprising: a silicon-based substrate; and a protective layer covering the silicon-base substrate, the protective layer having a TMDC material, being uniform and having a thickness below about 8 nm.

In accordance with another aspect, there is provided a method for manufacturing a silicon photoanode, the method comprising: applying a layer of TMDC material on a silicon-based substrate using a molecular beam epitaxy (MBE) technique.

It will be understood that the expression ‘computer’ as used herein is not to be interpreted in a limiting manner. It is rather used in a broad sense to generally refer to the combination of some form of one or more processing units and some form of memory system accessible by the processing unit(s). Similarly, the expression ‘controller’ as used herein is not to be interpreted in a limiting manner but rather in a general sense of a device, or of a system having more than one device, performing the function(s) of controlling one or more devices.

It will be understood that the various functions of a computer or of a controller can be performed by hardware or by a combination of both hardware and software. For example, hardware can include logic gates included as part of a silicon chip of the processor. Software can be in the form of data such as computer-readable instructions stored in the memory system. With respect to a computer, a controller, a processing unit, or a processor chip, the expression “configured to” relates to the presence of hardware or a combination of hardware and software which is operable to perform the associated functions.

Many further features and combinations thereof concerning the present improvements will appear to those skilled in the art following a reading of the instant disclosure.

### DESCRIPTION OF THE FIGURES

In the figures,

FIG. 1 is a schematic view of an example of a photoelectrochemical cell with a silicon photoanode, in accordance with an embodiment;

FIG. 2 is a flow chart of a method for manufacturing the silicon photoanode of FIG. 1;

FIG. 3A is a schematic view of an example of a p+-n Si photoanode protected by few-layer 2H MoSe₂, showing dark blue and purple colored atoms denote Se, and Mo, respectively, in accordance with an embodiment;

FIG. 3B is a graph showing the energy band diagram of MoSe₂/p+-n Si photoanode of FIG. 3A under AM1.5G light illumination, in accordance with an embodiment;

FIG. 4A is a graph of XPS measurements showing two peaks at 229.2 and 232.4 eV corresponding to Mo⁴⁺, in accordance with an embodiment;

FIG. 4B is a graph of XPS measurements showing doublet of 54.9 and 55.6 eV corresponding to Se²⁻ for MoSe₂ film, in accordance with an embodiment;

FIG. 4C is a graph showing a Raman spectra for MoSe₂ film showing E_{1g}, A_{1g} and E_{2g1} modes, in accordance with an embodiment;

FIG. 4D is an AFM image of MoSe₂ surface on Si wafer; with a scale bar of 400 nm, for a thickness of MoSe₂ layer of ˜3 nm, in accordance with an embodiment;

FIG. 5A is a graph showing J-V characteristics of the MoSe₂/p+-n Si photoanode of FIG. 3A with MoSe₂ thicknesses of 1 nm (green curve), 3 nm (red curve), 5 nm (blue curve) and 10 nm (yellow curve) under AM1.5G one sun illumination (100 mW/cm₂) and dark condition (black dashed curve) in 1M HBr, in accordance with an embodiment;

FIG. 5B is a graph showing ABPE measurements for the MoSe₂/p+-n Si photoanode of FIG. 3A with different MoSe₂ thicknesses and showing that the highest ABPE of 13.8% was measured for Si photoanode with 3 nm MoSe₂ protection layer at ˜0.5 V vs RHE, in accordance with an embodiment;

FIG. 5C is a graph showing IPCE of the MoSe₂/p+-n Si photoanode of FIG. 13A under AM1.5G one sun illumination (100 mW/cm²) in 1 M HBr, showing that the peak value is ˜75% at 620 nm, in accordance with an embodiment;

FIG. 6A is a graph showing OCP vs RHE for the MoSe₂/p+-n Si photoanode of FIG. 13A under chopped light illumination, with a red curve showing OCP for MoSe₂/p+-n Si photoanode, and a dotted blue curve showing OCP for p+-n Si without MoSe₂, in accordance with an embodiment;

FIG. 6B is a chronopotentiometry graph showing stability of the MoSe₂/p+-n Si photoanode of FIG. 13A, showing stable voltage (vs RHE) ˜0.38 V for ˜14 hours at ˜2 mA/cm² under AM 1.5G one sun illumination in 1 M HBr, in accordance with an embodiment;

FIG. 7 is an enlarged view of the graph of FIG. 5A;

FIG. 8 is a graph showing J-V characteristics of MoSe₂ thin films (˜3 nm thick) on p⁺-n Si wafer with different growth combinations of growth temperature (T_{G}) and annealing temperature (T_{A}) under AM1.5G one sun illumination 100 mW/cm² and dark condition (black dashed curve) in 1M HBr with T_{G}: 250° C./T_{A}: 250° C. (red curve), T_{G}: 400° C./T_{A}: 650° C. (blue curve), and T_{G}: 200° C./T_{A}: 200° C. (yellow curve);

FIG. 9. is an optical microscopy image of MoSe₂ with a thickness of ˜3 nm where the atomic force microscopy measurement has been performed near the black bar region as shown in the inset;

FIG. 10 is a graph showing LSV curves illustrating a comparison between with (red curve) and without (light blue curve) MoSe₂ thin film on p⁺-n Si photoanode in 1M HBr solution under the illumination of AM1.5G one sun (100 mW/cm²) and dark condition (black dashed curve), with the inset showing the comparison between p⁺-n Si solar cell under AM1.5G one sun illumination (light blue curve) and dark condition (dotted black curve) in the potential range of 0.7-1 V vs RHE;

FIG. 11 is a graph showing J-V characteristics of MoSe₂/p⁺-n Si photoanode under different illumination conditions in 1 M HBr under various illumination intensities: 0.3 Sun (yellow curve), 0.5 Sun (blue curve), 1 Sun (red curve) and 2 Suns (green curve) and dark condition (black dashed curve);

FIG. 12 is a graph showing Mott-Schottky characteristics of MoSe₂/p⁺-n Si photoanode measured at 1 KHz under dark condition (blue curve) in 1M HBr and the extrapolated linear fit (green dashed line) intercepts the x-axis at 0.46 V vs RHE, the positive slope indicating n-type behaviour which is characteristic of photoanode, the V_{fb} from this analysis is ˜0.46 V;

FIG. 13A is a graph showing a chronoamperometry study for MoSe₂/p⁺-n Si photoanode illustrating stable photocurrent density of ˜26 mA/cm² at 0.6 V vs RHE for 1 hour;

FIG. 13B is a graph showing XPS measurements after 1 hr chronoamperometry stability test for Mo;

FIG. 13C is a graph showing XPS measurements after 1 hr chronoamperometry stability test for Se, showing Mo:Se ratio of ˜1:2; and

FIG. 14 is a graph showing hole injection efficiency for MoSe₂/p⁺-n Si photoanodes with different MoSe₂ thicknesses under AM 1.5G one sun illumination in 1 M HBr, where the shaded region indicates hole injection efficiency between >80%.

### DETAILED DESCRIPTION

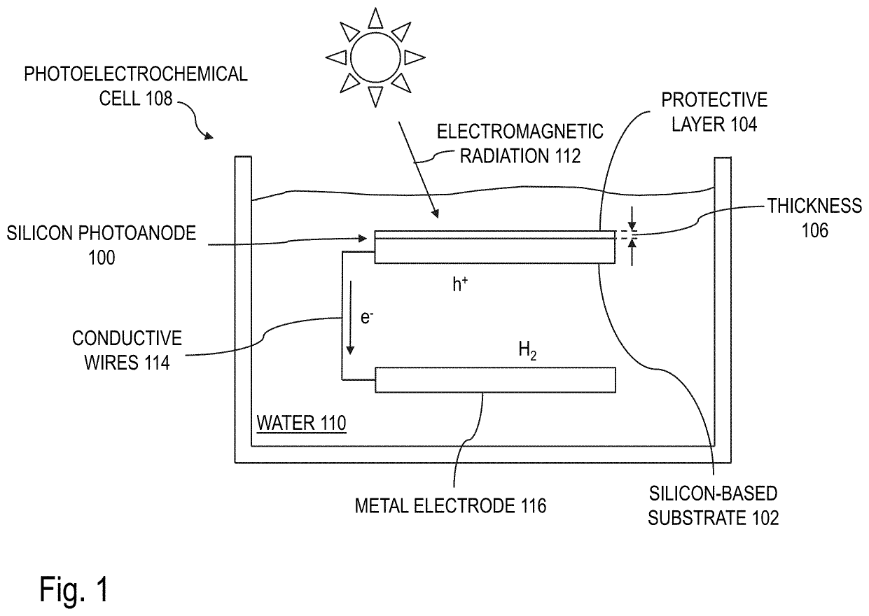

FIG. 1 shows an example of a silicon photoanode 100, in accordance with an embodiment. As shown in this example, the silicon photoanode 100 generally has a silicon-based substrate 102, and a protective layer 104 covering the silicon-base substrate 102.

The protective layer 104 is made of a transition metal dichalcogenide (TMDC) material. In some embodiments, the TMDC material is MoSe₂. However, Indeed, based on the results obtained by using MoSe₂ presented below in Examples 1 and 2, the inventors believe that any other TMDC material having corrosion-resistant properties can be used as well in alternate embodiments. For instance, examples of TMDC material can include, but not limited to, WSe₂, MoSe₂, MoS₂, MoTe₂, WTe₂ and WS₂.

The protective layer 104 is also uniform. Indeed, the protective layer 104 is uniform in the sense that the protective layer 104 has a uniform thickness over at least a given area. The given area can be greater than 200 mm², preferably greater than 25 mm² and most preferable greater than 50 mm², depending on the embodiment.

The protective layer 104 also has a thickness 106 which is below 8 nm. In some embodiments, the thickness 106 is preferably below 5 nm and most preferably below 4 nm. Still to provide the sought uniformity, it was found that the thickness 106 of the protective layer 104 is above at least 2 nm, below which surface defects can prevent light to propagate through the protective layer 104.

As shown in FIG. 1, the silicon photoanode 100 is part of a photoelectrochemical cell 108. In this specific embodiment, the photoelectrochemical cell 108 can produce electrical energy or hydrogen. More specifically, the photoelectrochemical cell 108 involves electrolysation of water to hydrogen and oxygen gas by irradiating the silicon photoanode 100 immerged in water 110 with electromagnetic radiation such as sunlight 112. In this way, incoming sunlight 112 can excite free electrons near the surface of the silicon photoanode 100, which then flow through wires 114 to a metal electrode 116, where four of them react with four water molecules to form two molecules of hydrogen and four OH groups. The OH groups flow through the liquid electrolyte to the surface of the silicon photoanode 100. There, the four OH groups react with the four holes associated with the four photoelectrons, the result being two water molecules and an oxygen molecule.

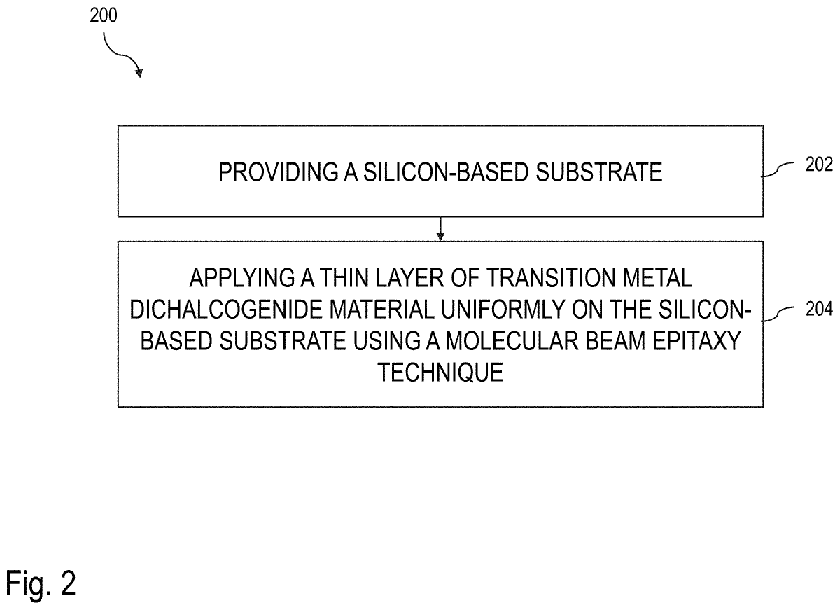

As will be described below in further details, the protective layer 104 of the silicon photoanode 100 can be applied (i.e., deposited) using molecular beam epitaxy (MBE). More specifically, FIG. 2 shows an example of a method 200 for manufacturing the silicon photoanode 100. The method 200 includes a step 202 of providing the silicon-based substrate 102, and a step 204 of applying a layer of TMDC material on the silicon-based substrate 102 using a MBE technique. In embodiments where the TMDC material is MoSe₂, the step 204 can include heating the silicon-based substrate 102 to temperatures in the range of 200-450° C., introducing a Mo molecular beam under Se-rich conditions for about 18-180 minutes, with a deposition rate of about 0.01 Å/s for MoSe₂. MoSe₂ can also be manufactured using chemical vapor deposition (CVD) method. In this method MoSe₂ is synthesised on Si wafer with a relatively thick SiO₂ layer using MoO₃ powder and Se pellets as molybdenum and selenium precursors in a furnace operating at a high temperature (>700° C.) under atmospheric conditions.

### Example 1—A High Efficiency Si Photoanode Protected by Few-Layer MoSe₂

To date, the performance of semiconductor photoanodes has been severely limited by oxidation and photocorrosion. Here, use of earth-abundant MoSe₂ as a surface protection layer for Si-based photoanodes is reported. Large area MoSe₂ film was grown on p⁺-n Si substrate by molecular beam epitaxy. It is observed that the incorporation few-layer (˜3 nm) epitaxial MoSe₂ can significantly enhance the performance and stability of Si photoanode. The resulting MoSe₂/p⁺-n Si photoanode produces a light-limited current density of 30 mA/cm² in 1M HBr under AM 1.5G one sun illumination, with a current-onset potential of 0.3 V vs reversible hydrogen electrode (RHE). The applied bias photon-to-current efficiency (ABPE) reaches up to 13.8%, compared to the negligible ABPE values (<0.1%) for a bare Si photoanode under otherwise identical experimental conditions. The photoanode further produced stable voltage of ˜0.38 V vs RHE at a photocurrent density of ˜2 mA/cm² for ˜14 hrs under AM 1.5G one sun illumination. This work shows the extraordinary potential of two-dimensional transitional metal dichalcogenides in photoelectrochemical application and will contribute to the development of low cost, high efficiency, and highly stable Si-based photoelectrodes for solar hydrogen production.

The ever-increasing demand for energy has inspired intensive research on the development of sustainable and renewable energy sources to diminish our dependence on fossil fuels. PEC water splitting is one of the most promising methods to convert solar energy into storable chemical energy in the form of H₂ production, which is a clean and eco-friendly alternative fuel that can be stored, distributed and consumed on demand. A PEC device generally consists of a semiconductor photocathode and photoanode, which collect photo-generated electrons and holes to drive H₂ and O₂ evolution reaction, respectively. For practical application, it is essential that the semiconductor photoelectrodes can efficiently harvest sunlight, are of low cost, and possess a high level of stability in aqueous solution. To date, however, it has remained challenging, especially for semiconductor photoanodes, to simultaneously meet these demands. Recently, Fe₂O₃, BiVO₄, Ta₃N₅, GaP, GaN/InGaN and Si have been intensively studied as photoanodes. Among these materials, Si is a low cost and abundantly available photoabsorber material, with an energy band-gap of 1.12 eV, which has advantages such as high carrier mobility and absorption of a substantial portion of sunlight. Si, however, is highly prone to photocorrosion. Various surface protection schemes, including the use of TiO₂ and NiOₓ, have been developed to improve the stability of Si-based photoanodes. The use of wide bandgap and/or thick protection layers, however, severely limits the extraction of photoexcited holes, leading to very low photocurrent density and extremely poor applied bias photon-to-current efficiency (ABPE) in the range of 1-2%. Recently, by using NiFe alloy as a surface protection coating with LDH co-catalyst, an ABPE of ˜4.3% has been demonstrated for Si photoanodes, which however, still lags significantly behind those (˜10-15%) for Si-based photocathodes.

Studies have shown that earth-abundant two-dimensional (2D) transition metal dichalcogenides (TMDC), including MoS₂, WSe₂, MoSe₂ and WS₂, possess remarkable properties for PEC application. The edge states of monolayer TMDC can provide catalytic sites for H₂ evolution reaction (HER), and TMDCs have also been employed as photoanodes for oxidation reaction. Recent first principles calculations have further revealed that perfect 2D TMDCs are chemically inert, and their excellent stability in acidic electrolyte has also been reported. Due to the van der Waals bonds, high quality interface can be formed when 2D TMDC is deposited on Si surface, which can offer an effective means to passivate the Si surface and minimize surface recombination. To date, however, there have been no reports on the use of 2D TMDCs as a surface protection layer for semiconductor photoanodes. This has been limited, to a large extent, by the lack of controllable synthesis process of 2D TMDCs. The commonly used exfoliation process is not suited to produce uniform TMDCs with controlled thickness and high-quality interface on a large area wafer. Alternatively, the growth/synthesis of 2D TMDCs using bottom-up approaches such as chemical vapor deposition (CVD) and molecular beam epitaxy (MBE) have been intensively studied. The latter method, which utilizes ultrahigh vacuum (UHV) environment, is highly promising to produce high purity and controllable film thickness.

Herein, the MBE growth of large area MoSe₂ film on p⁺-n Si substrate has been investigated and has been further studied the PEC performance of Si photoanode with MoSe₂ protection layers of varying thicknesses. It is observed that the incorporation an ultrathin (˜3 nm) epitaxial MoSe₂ can significantly enhance the performance and stability of p⁺-n Si photoanode. The MoSe₂/p⁺-n Si photoanode produces a nearly light-limited current density of ˜30 mA/cm² in 1M HBr under AM 1.5G one sun illumination, with a current-onset potential of 0.3 V vs RHE. The ABPE reaches up to 13.8%, compared to the negligible ABPE values (<0.1%) of bare Si photoanode. Moreover, nearly 100% hole injection efficiency is achieved under a relatively low voltage of <0.6 V vs RHE. The chronovoltammetry analysis for the photoanode shows a stable voltage of ˜0.38 V vs RHE for ˜14 hrs at ˜2 mA/cm². The effect of MoSe₂ layer thickness on the PEC performance is also investigated. This work shows the extraordinary potential of 2D TMDC in PEC application and promises a viable approach for achieving high efficiency Si-based photoanodes.

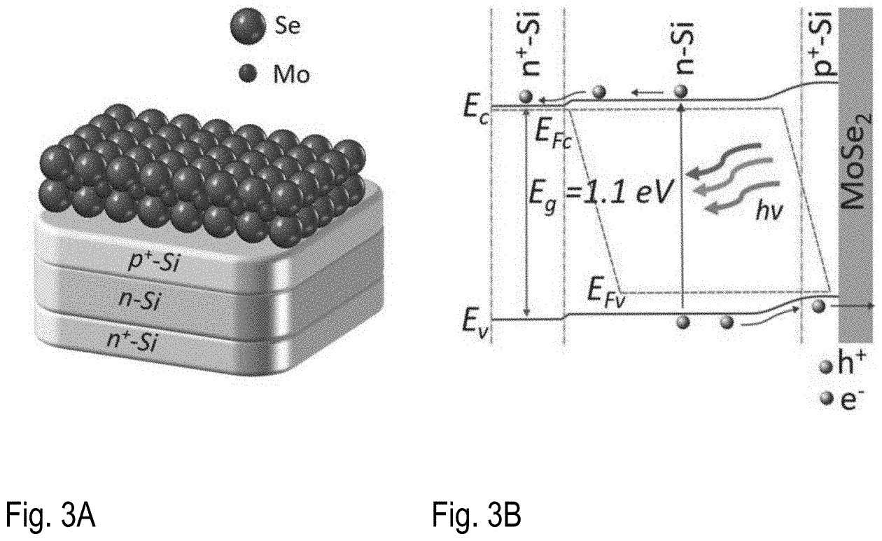

Schematically shown in FIG. 3a, MoSe₂ films were grown on p⁺-n Si substrate using a Veeco GENxplor MBE system. The fabrication of p⁺-n Si wafer is described in Example 2 below. As described below, the MBE growth of MoSe₂ thin film results in 2H structure, which is schematically shown in FIG. 3A. The energy band diagram of the MoSe₂/p⁺-n Si photoelectrode is illustrated in FIG. 3B. Photoexcited holes can tunnel through the thin MoSe₂ protection layer to participate in oxidation reaction, while photoexcited electrons from Si migrate towards the counter electrode to participate in H₂ evolution reaction. The MoSe₂ layer also suppresses surface recombination. It is seen that the thickness of MoSe₂ is critical: it needs to be optimally designed and synthesized to protect the Si surface against photocorrosion and oxidation without compromising the hole transport and extraction.

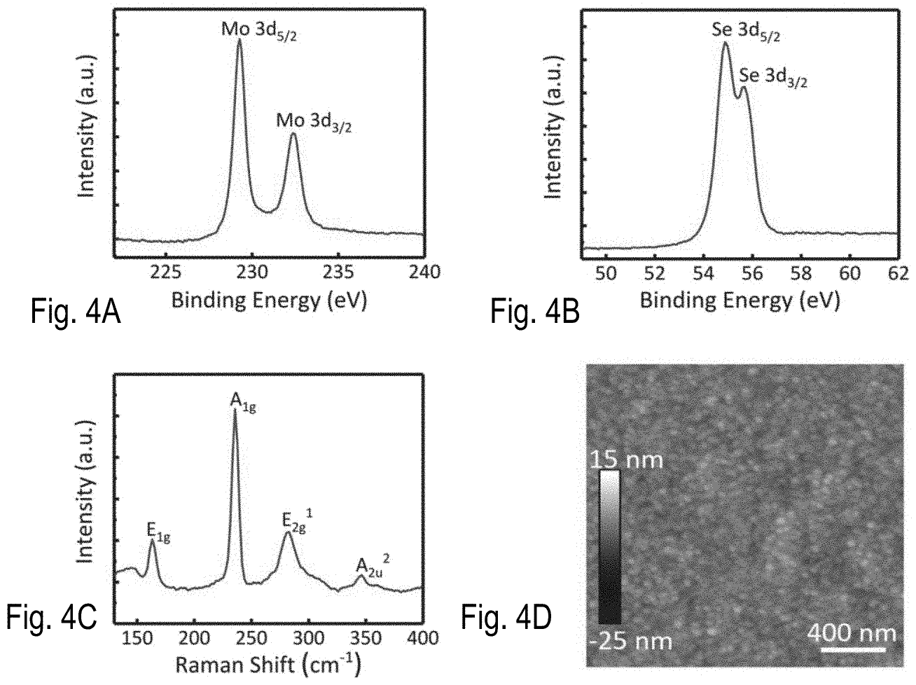

Properties of MoSe₂ grown on Si wafer by MBE are characterized using X-ray photoelectron spectroscopy (XPS), atomic force microscopy (AFM), and micro-Raman spectroscopy. The composition of MoSe₂ layers is first analyzed by using XPS measurement (Thermo Scientific K-Alpha XPS system with a monochromatic Al Kα source (hv=1486.6 eV)). The binding energy of carbon (284.58 eV) was used as a reference peak position for the measurements. FIG. 4A shows two peaks located at 229.2 and 232.4 eV which originated from Mo 3d_{5/2} and Mo 3d_{3/2} orbitals, respectively, confirming the existence of Mo⁴⁺. Shown in FIG. 4B, a single doublet of Se 3d_{5/2} at 54.9 eV and Se 3d_{3/2} at 55.6 eV can be observed, corresponding to the oxidation state of −2 for Se. These results confirm the formation of MoSe₂ on the Si wafer. Micro-Raman spectroscopy was carried out using a 514 nm argon ion laser as the excitation source. Illustrated in FIG. 4C, emission peaks at 163.02, 235.67, 281.89 and 346.18 cm⁻¹ have been identified, which correspond to E_{1g}, A_{1g}, E_{2g}¹ and A₂ᵤ² modes, respectively. The most prominent peaks are A_{1g} and E_{2g}¹ modes, which are related to the out-of-plane vibration and in-plane vibration, respectively. These Raman modes, unique to 2H—MoSe₂, have been observed in previous reports and suggest the formation of 2H-phase MoSe₂ on Si wafer. Shown in FIG. 4D is the AFM image of MoSe₂ film (˜3 nm thick) grown on Si (see Example 2 below).

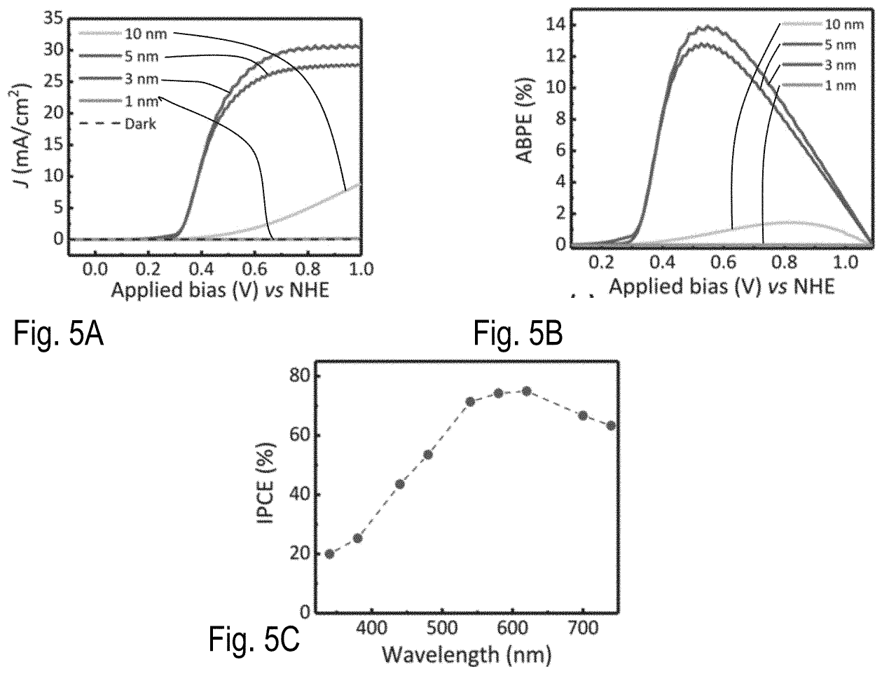

We have subsequently investigated the PEC performance of MoSe₂/p⁺-n Si photoanode. The linear scan voltammogram (LSV) of MoSe₂/p⁺-n Si photoanodes with various MoSe₂ thicknesses is shown in FIG. 5A under both dark and illumination conditions. Further details of the LSV for p⁺-n Si photoanode with and without any MoSe₂ coverage are shown in Example 2 below. It is observed that the p⁺-n Si photoanode exhibit negligible photocurrent, which is directly related to the rapid surface oxidation of unprotected Si surface. Superior performance was achieved for MoSe₂/p⁺-n Si photoanodes with ˜3 nm MoSe₂. Shown in FIG. 5A, the current-onset potential is ˜0.3 V vs RHE, with a nearly light-limited current density ˜30 mA/cm² measured at ˜0.8 V vs RHE (see in Example 2 below). The measurement of light-limited current density also suggests that the thin MoSe₂ layer can effectively passivate the Si surface to minimize surface recombination. The achievement of high photocurrent density for a photoanode under relatively low bias voltage is essentially required to realize unassisted solar H₂ generation when paired with a high-performance photocathode for PEC tandem system. With increasing MoSe₂ thickness to ˜5 nm, the photocurrent density is reduced to ˜27 mA/cm², due to the less efficient tunneling of photoexcited holes from Si to electrolyte. It is worth mentioning that the reduction of photocurrent density may be partly related to the increased absorption of MoSe₂ protection layer due to the slightly larger thickness. Previous studies have shown that the hole tunneling through the protection layer is extremely sensitive to the layer thickness. In this study, since the surface roughness is relatively large (˜1-2 nm) for MoSe₂ layers, a relatively small difference in the photocurrent density was observed by increasing the thicknesses from 3 nm to 5 nm. Also for these reasons, it is observed that decreasing the MoSe₂ thickness to ˜1 nm leads to negligible photocurrent density, due to the uneven surface coverage and the resulting oxidation of the Si surface. With further increasing the MoSe₂ thickness to ˜10 nm, both the photocurrent density and current-onset potential become significantly worse, due to the suppressed tunneling for photo-generated holes. In these studies, the underlying Si wafers are identical and are contacted from the backside. Therefore, the drastically different PEC characteristics are directly related to the thicknesses of MoSe₂ protection layer, which provides unambiguous evidence that an optimum thickness of epitaxial MoSe₂ can protect the semiconductor photoanode without compromising the extraction of photo-generated holes. Through detailed studies on the MoSe₂ growth temperature and in situ annealing conditions (see in Example 2 below), it was identified that the best performing MoSe₂/p⁺-n Si photoanodes could be achieved for MoSe₂ thickness ˜3 nm and growth temperature in the range of 200 to 400° C.

The ABPE of the photoanode was derived using the Equation (1),

$$η ( \% ) = \frac{J ( {E}_{rev}^{0} - {V}_{RHE} )}{{P}_{in}} \times 100 \qquad ( 1 )$$

where J is the photocurrent density, Eᵣₑᵥ⁰ is the standard electrode oxidation potential for Br⁻, V_{RHE} is the applied bias vs RHE, and Pᵢₙ is the power of the incident light (i.e. 100 mW/cm²). Variations of the ABPE vs applied bias are shown in FIG. 5B for MoSe₂/p⁺-n Si photoanodes with MoSe₂ thicknesses varying from 1 to 10 nm. It is seen that a maximum ABPE of 13.8% is achieved at ˜0.5 V vs RHE for MoSe₂/p⁺-n Si photoanodes with MoSe₂ thickness ˜3 nm. The maximum ABPE decreases to ˜12% and 2% with increasing MoSe₂ thickness to 5 and 10 nm, respectively, and to negligible values for MoSe₂ thicknesses of 1 nm or less. The reported ABPE of 13.8% is significantly higher than previously reported TMDC-based photoanode in polyhalide-based redox systems and hole scavenger solutions. The incident-photon-to-current-efficiency (IPCE) of MoSe₂/p⁺-n Si photoanode with MoSe₂ thickness ˜3 nm was further measured. The measurement was conducted at 1 V vs RHE in 1M HBr in a three-electrode system. The IPCE was calculated using the Equation (2),

IPCE (%)=(1240×I)/(λ×Pᵢₙ)×100 (2)

where I is photocurrent density (mA/cm²), λ is the incident light wavelength (nm) and Pᵢₙ is the power density (mW/cm²) of the incident illumination. Shown in FIG. 5C, the maximum IPCE is above 70%.

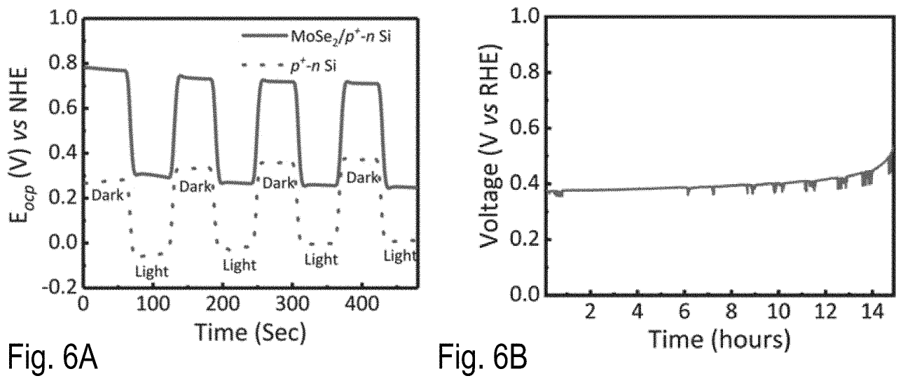

We have further studied the open circuit potential (OCP) of MoSe₂/p⁺-n Si photoanodes, which was measured vs RHE under chopped light illumination. A negative shift of the OCP was measured under light illumination, which is characteristic of photoanodes. The OCP (E_{ocp} vs RHE) of p⁺-n Si and MoSe₂/p⁺-n Si with MoSe₂ thickness ˜3 nm is shown in FIG. 6A. The p⁺-n Si photoanode (dotted blue curve) exhibits a dark potential ˜0.3 V and an illuminated potential ˜0 V, with a change in OCP ˜0.3 V. The change in OCP under dark and illumination conditions is less than the photovoltage ˜0.53 V for a typical p⁺-n Si junction, which is due to the change of potential drop across the Helmholtz layer at the Si/electrolyte interface. E_{ocp} of the MoSe₂/p⁺-n Si photoanode (solid red curve) is ˜0.3 V and 0.8 V vs RHE under illumination and dark conditions, respectively. The potential difference under light and dark conditions is ˜0.5 V, which is nearly identical to the flat-band potential (V_{fb}) derived from the Mott-Schottky measurements (see in Example 2 below). Moreover, the light-induced OCP shift (˜0.5 V) for MoSe₂/p⁺-n Si photoanode is reasonably close to the open circuit voltage expected from the p⁺-n Si junction. The negligible voltage loss further confirms that the thin (˜3 nm) MoSe₂ layer can effectively protect the Si surface from oxidation in acidic solution and that photoexcited holes can tunnel efficiently through the MoSe₂ layer. Chronovoltammetry experiments were further performed to test the stability of MoSe₂/p⁺-n Si photoanode at photocurrent density of ˜2 mA/cm² under AM 1.5G one sun illumination. Shown in FIG. 6B, the voltage stays nearly constant at ˜0.38 V vs RHE, and there is no any apparent degradation under continuous illumination for ˜14 hrs. The chronoamperometry experiment (see in Example 2 below) also showed stable photocurrent density of ˜26 mA/cm² for 1 hr at 0.6 V vs RHE and subsequent XPS measurements on that sample showed Mo:Se ratio of 1:2.

The underlying mechanisms for the dramatically improved performance of Si-based photoanodes are described. The use of a MoSe₂ protection layer allows for the efficient tunneling of photoexcited holes from p⁺-n Si to electrolyte through the MoSe₂ barrier, compared to the previously reported wide bandgap, e.g. TiO₂ protection layer. This is evidenced by the very large hole injection efficiency (>80%) even at a relatively low potential (˜0.5 V vs RHE) (see in Example 2 below). Moreover, the MoSe₂ layer is sufficiently thin (˜3 nm) to allow for most of the incident light to pass through, thereby leading to a nearly light-limited current density. For a perfect MoSe₂ sheet, there are no dangling bonds and surface states, since the lone pair of electrons on chalcogen (Se) atom terminate on the surface. Recent first principles calculations have further shown that a perfect MoSe₂ sheet is intrinsically chemically inert and can effectively protect against oxidation and photocorrosion, which explains the dramatically improved performance and stability, compared to a bare Si photoanode. It is also worthwhile mentioning that the enhanced performance is not likely due to the catalytic property of MoSe₂, since the MoSe₂ layer showed no activity under dark condition (see FIG. 10 and FIG. 5A) and the 1 nm thickness sample (in FIG. 5A) showed very poor light scan. To further improve the device stability, it is essential to eliminate, or minimize the presence of Se vacancy and related defects, which are known to significantly enhance the oxidation effect.

In conclusion, it is demonstrated herein that the integration of few-layer MoSe₂ can protect the surface of an otherwise unstable Si photoelectrode in corrosive environment, while allowing for efficient electron/hole tunneling between Si photoanode and solution. The MoSe₂/p⁺-n Si photoanode exhibit remarkable PEC performance, including an excellent current-onset potential of 0.3 V vs RHE, a light-limited current photocurrent density of ˜30 mA/cm² under AM1.5G one sun illumination, an ABPE of 13.8%, and relatively high stability in acidic solution. For future work, it would be important to investigate and optimize the MoSe₂/Si heterointerface, to engineer the surface properties of MoSe₂, and to couple with suitable water oxidation co-catalysts, which will further improve the current-onset potential and enhance the photoanode performance and stability in PEC water splitting. These studies will contribute to the development of low cost, high efficiency, and highly stable Si-based photoelectrodes for solar H₂ production.

Fabrication of p⁺-n Si:

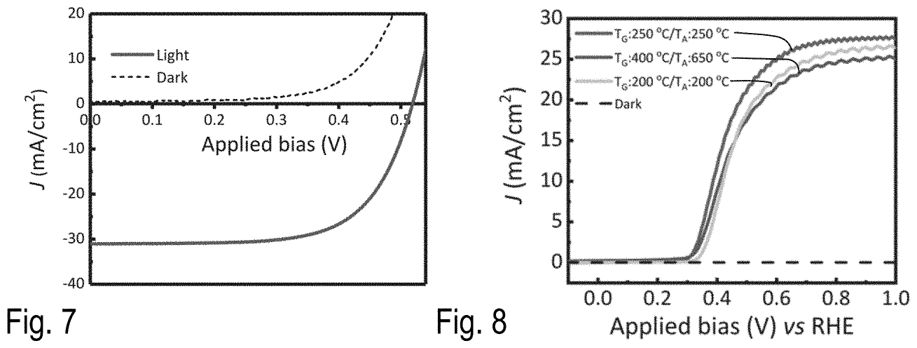

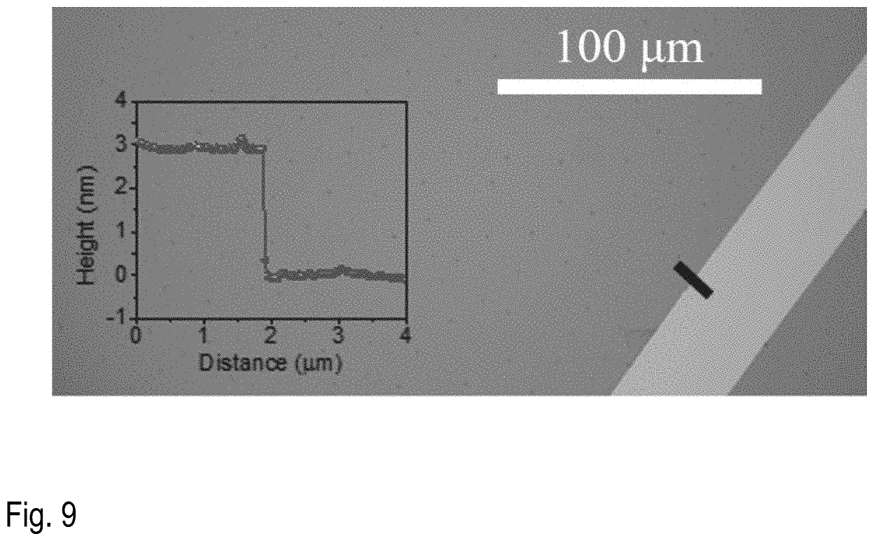

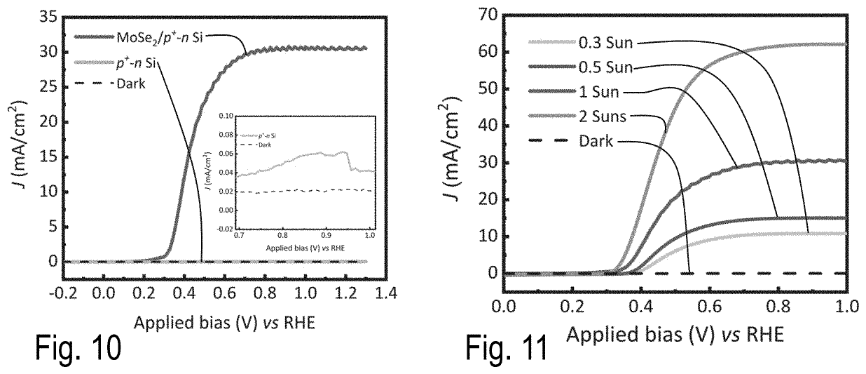

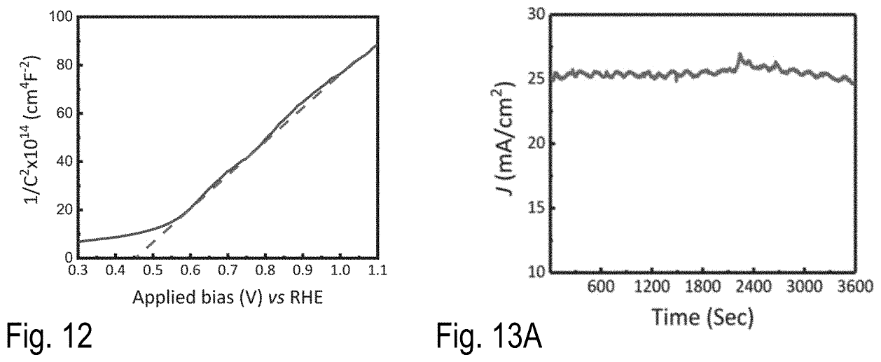

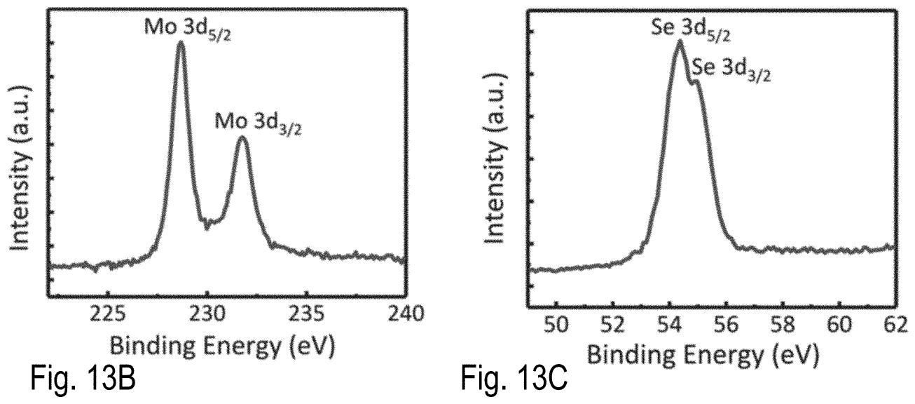

Double side polished n-type Si(100) wafers (WRS Materials, thickness: 254-304 μm; resistivity: 1-10 Ω·cm) were spin-coated with liquid boron dopant precursor (Futurrex, Inc.) on one side to form the p⁺-Si emitter and liquid phosphorus dopant precursor (Futurrex, Inc.) on the other side to form the n⁺-Si back field layer. Subsequently, the thermal diffusion process was conducted at 950° C. for 240 min under argon gas flow in a furnace. The residue of the precursor was removed in buffered oxide etch solution. To measure the efficiency of the solar cells, metal contacts were made on n-side and p-side by depositing Ti/Au and Ni/Au respectively using e-beam evaporator. Shown in FIG. 7, J_{sc} of the device is ˜31 mA/cm², V_{oc} is ˜0.52 V, and the energy conversion efficiency is ˜11%.

PEC Measurements:

The PEC reaction was conducted in 1 mol/L HBr solution using a potentiostat (Gamry Instruments, Interface 1000) with MoSe₂/p⁺-n Si, silver chloride electrode (Ag/AgCl), and Pt wire as the working, reference, and counter electrode, respectively. The working electrode was prepared by cleaving the MoSe₂/p⁺-n Si wafer into area sizes of 0.2-1 cm². A Ga—In eutectic (Sigma Aldrich) alloy was deposited on the backside of the Si wafer to form ohmic contact, which was subsequently connected to a Cu wire using silver paste. The entire sample except the front surface was covered by insulating epoxy and placed on a glass slide. A solar simulator (Newport Oriel) with an AM1.5 G filter was used as the light source, and the light intensity was calibrated to be 100 mW/cm² for all subsequent experiments. The conversion of the Ag/AgCl reference potential to RHE is calculated using the Equation (3),

E_{(NHE)}=E_{Ag/AgCl}+E_{Ag/AgCl}⁰+0.059×pH (3)

where E_{Ag/AgCl}⁰ is 0.197 V, and pH of the electrolyte is nearly zero.

MBE Growth of MoSe₂:

During the growth process, molybdenum (Mo) was thermally evaporated using an e-beam evaporator (Telemark Inc.) retrofitted in the MBE reaction chamber. A two-step MBE growth process was developed for MoSe₂ thin film. In the first step, the substrate was heated to temperatures in the range of 200-450° C., and Mo molecular beam was introduced under Se-rich conditions (Se beam equivalent pressure (BEP) of 3.5×10⁻⁷ torr) for 18-180 minutes, with a deposition rate ˜0.01 Å/s for MoSe₂. The resulting MoSe₂ thicknesses vary between 1 nm and 10 nm. In the second step an in situ thermal annealing was performed under Se flux for 10 mins in the temperature range of 200-650° C. (see in Example 2 below).

### Example 2—Supporting Information for Example 1

The following paragraphs discuss the fabrication of p⁺-n Si Wafer, the effect of MoSe₂ growth conditions on the PEC performance, the structural characterization of MoSe₂, the PEC performance of p⁺-n Si photoanode, the PEC performance of MoSe₂/p⁺-n Si photoanode, the Mott-Schottky Characteristics of MoSe₂/p⁺-n Si photoanode, the stability of MoSe₂/p⁺-n Si photoanode, and the n the hole injection efficiency.

To study the effect of growth temperature (T_{G}) and annealing temperature (T_{A}) in the two step MBE growth (see main text), samples with different growth and annealing temperature combinations were grown by keeping the same thickness of 3 nm for the MoSe₂ film. Shown in FIG. 8, it can be observed that the best PEC performing sample, in terms of on-set voltage and photocurrent density, is with growth temperature of 250° C. and annealing temperature of 250° C. The sample with growth temperature of 400° C. showed lower photocurrent density and the sample with growth temperature 200° C. produced a lower on-set potential compared to the sample with growth temperature 250° C.

J-V curves (see Fig. S10) show that the photocurrent density for p⁺-n Si photoanode (light blue curve) without MoSe₂ protection layer is almost negligible, compared to MoSe₂/p⁺-n Si photoanode (red curve). This can be attributed to the fact that unprotected Si surface is highly prone to oxidation in acidic solution, which results in extremely low current density and poor stability. As shown by the red curve in FIG. 10, the sample with MoSe₂ protection layer exhibited a high saturated photocurrent density of ˜30 mA/cm².

The saturated photocurrent density of ˜30 mA/cm² is close to the maximum theoretical current density for c-Si, considering surface reflection loss of the incident light. In fact, the measured photocurrent density is nearly identical to the J_{sc} of the Si solar cell shown in FIG. 7, which suggests that photo-generated holes in Si can effectively tunnel through the thin MoSe₂ protection layer and participate in oxidation reaction. The PEC performance has been further tested by varying the light intensity. Shown in FIG. 11 are the measurements performed under different light illuminations: 0.3 Sun, 0.5 Sun, 1 Sun and 2 Suns, with the saturated photocurrent being 11 mA/cm², 15 mA/cm², 30 mA/cm² and 60 mA/cm², respectively. The photocurrent density scales linearly with the light intensity. The light-limited photocurrent density values also agree well with previous reports.

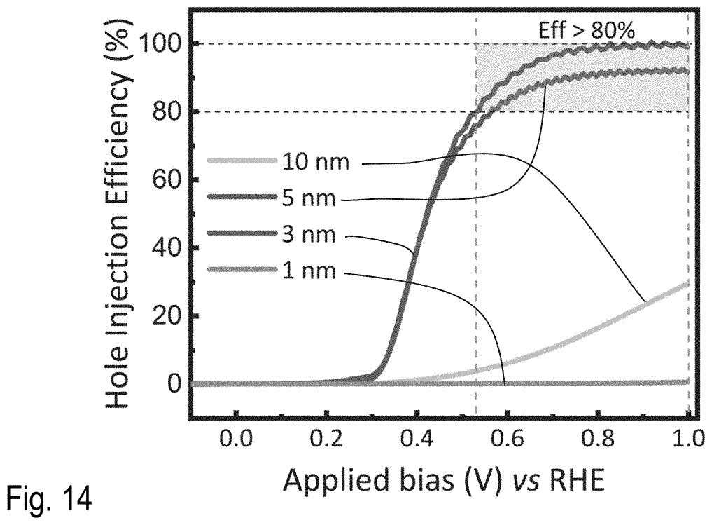

The light-limited current density for MoSe₂/p⁺-n Si solar cell photoanode is 30 mA/cm². Based on this observation, the hole injection efficiency for photoanodes was calculated with different thicknesses of MoSe₂. As seen from FIG. 14, at relatively low bias ˜0.5-0.6 V vs RHE the hole injection efficiency is ≥80% for MoSe₂ thicknesses of 3 nm and 5 nm. The shaded region in FIG. 14 indicates hole injection efficiency >80%. The achievement of very high hole injection efficiency at a relatively low biasing voltage suggests the efficient tunneling of photogenerated holes from Si to solution through the MoSe₂ protection layer.

As can be understood, the examples described above and illustrated are intended to be exemplary only. For instance, although the silicon photoanode is described with reference to a photoelectrochemical cell, the silicon photoanode can be provided separately from the photoelectrochemical cell. Moreover, the silicon photoanode can be used in other contexts than that of the photoelectrochemical cell in alternate embodiments. The photoelectrochemical cell can be omitted. The scope is indicated by the appended claims.

What is claimed is:

1. A silicon photoanode comprising:
a silicon-based substrate; and
a protective layer covering the silicon-base substrate, the protective layer having a transition metal dichalcogenide (TMDC) material, being uniform and having a thickness below about 8 nm.

2. The silicon photoanode of claim 1 wherein the TMDC material is MoSe₂.

3. The silicon photoanode of claim 1 wherein the thickness is preferably below about 5 nm.

4. The silicon photoanode of claim 3 wherein the thickness is most preferably below about 4 nm.

5. The silicon photoanode of claim 1 wherein the thickness is above about 2 nm.

6. The silicon photoanode of claim 1 wherein the protective layer has been deposited using a molecular beam epitaxy (MBE) technique.

7. A method for manufacturing a silicon photoanode, the method comprising:
applying a layer of transition metal dichalcogenide (TMDC) material on a silicon-based substrate using a molecular beam epitaxy (MBE) technique.

8. The method of claim 7, wherein said TMDC material is MoSe₂, said applying comprising heating the silicon-based substrate to temperatures in the range of 200-450° C., introducing a Mo molecular beam under Se-rich conditions for about 18-180 minutes, with a deposition rate of about 0.01 Å/s for MoSe₂.
